(19) United States
(12) Patent Application Publication
(10) Pub. No.: US 2017/0017284 A1
(43) Pub. Date: Jan. 19, 2017

(54) POWER SUPPLY CIRCUIT FOR SOLID STATE DISK

(71) Applicant: HON HAI PRECISION INDUSTRY CO., LTD., New Taipei (TW)

(72) Inventors: CHUN-PO CHEN, New Taipei (TW); CHUN-AN LAI, New Taipei (TW); CHIA-MING YEH, New Taipei (TW)

(21) Appl. No.: 14/802,629

(22) Filed: Jul. 17, 2015

(51) Int. Cl. G06F 1/30; G11C 16/30

(52) U.S. Cl. CPC G06F 1/30; G11C 16/30

(57) ABSTRACT

A power supply circuit for a solid state disk includes a processor, a flash, a golden finger can be coupled to a direct current (DC) voltage, a boost converter coupled to the golden finger and configured to convert the DC voltage to a power voltage, a super-capacitor charger coupled to the boost converter, a super-capacitor coupled to the super-capacitor charger and configured to be charged by the super-capacitor charger and output a charge voltage, a control unit coupled to the super-capacitor and the boost converter, and a detection unit configured to compare the power voltage with a preset voltage. When the power voltage is less than the preset voltage, the control unit outputs the charge voltage to the processor and the flash; and when the power voltage is no less than the preset voltage, the control unit outputs the power voltage to the processor and the flash.

### FIELD

The subject matter herein generally relates to a power supply circuit for a solid state disk (SSD).

### BACKGROUND

A solid state disk (SSD) is generally secured to a motherboard of an electronic device by a mounting member, such as a mounting bracket, and an extra power plug is guided from the motherboard to couple to a connector of the SSD. The motherboard provides electronic power to the SSD via the extra power plug and the connector.

### BRIEF DESCRIPTION OF THE DRAWINGS

Implementations of the present technology will now be described, by way of example only, with reference to the attached figures.

FIG. 1 is a structure diagrammatic view of an embodiment of a SSD power supply circuit.

FIG. 2 is a block diagram of the power supply circuit of FIG. 1.

FIG. 3 is a block diagram of a control unit of the SSD power supply circuit of FIG. 2.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series and the like.

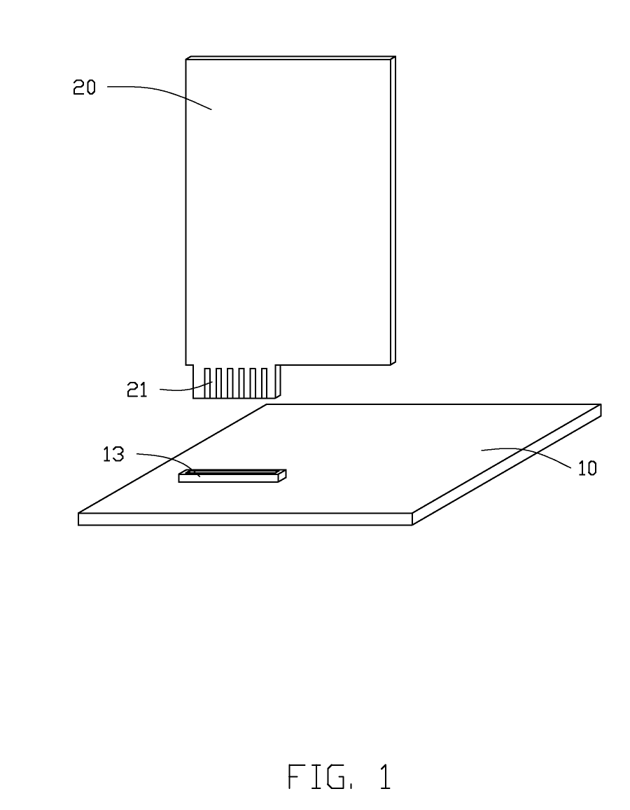

FIG. 1 illustrates an embodiment of a SSD power supply circuit can include a motherboard 10 and a SSD module 20.

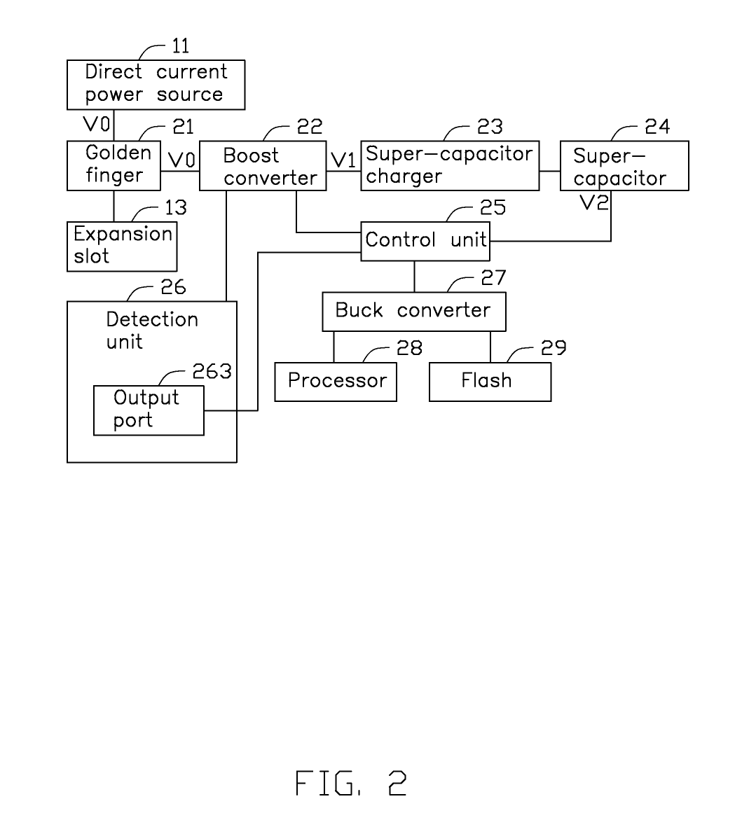

FIG. 2 illustrates the motherboard 10 including a direct current (DC) power source 11 and an expansion slot 13 coupled to the DC power source 11. The DC power source 11 is configured to output a direct current (DC) voltage V0. In a first embodiment, the DC voltage V0 is 1.2V, 1.35V, or 1.5V, and the expansion slot 13 is a memory card slot. In a second embodiment, the DC voltage V0 is 3.3 V, and the expansion slot 13 is a PCIE slot. In other embedment, the expansion slot 13 can be any idle slot couplable to a golden finger and a DC voltage less than 5V.

The SSD module 20 can include a golden finger 21, a boost converter 22, a super-capacitor charger 23, a super-capacitor 24, a control unit 25, a detection unit 26, a buck converter 27, a processor 28, and a flash 29.

The golden FIG. 21 is inserted into the expansion slot 13 to couple to the DC voltage V0.

The boost converter 22 is coupled to the golden FIG. 21 and configured to convert the DC voltage V0 to a power voltage V1. In at least one embodiment, the power voltage V1 is 5V, and the boost converter 22 is a chip typed LTC3425.

The super-capacitor charger 23 is coupled to the boost converter 22 and configured to receive the power voltage V1 and then charge the super-capacitor 24. In at least one embodiment, the super-capacitor charger 23 is a chip typed LTC3225.

The super-capacitor 24 is coupled to a first input port 251 of the control unit 25. The first input port 251 is configured to receive a discharge voltage V2. In at least one embodiment, the type of the super-capacitor 24 is HZ202F.

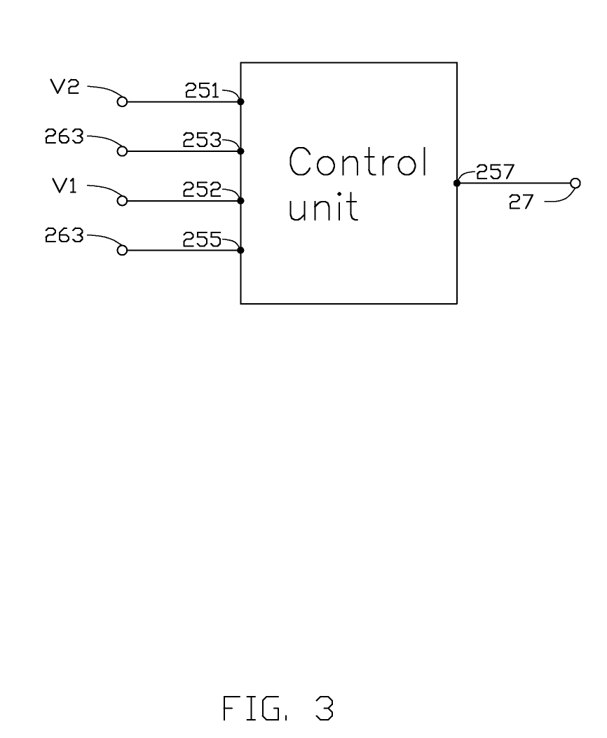

FIG. 3 illustrates the control unit 25 further includes a second input port 252, a first control port 253, a second control port 255, and an output port 257. The first control port 253 is configured to control the output port 257 to output the voltage of the first input port 251. The second control port 255 is configured to control the output port 257 to output the voltage of the second input port 252. In at least one embodiment, the control unit 25 is a chip typed LTC4413.

The second input port 252 is coupled to the boost converter 22 and configured to receive the power voltage V1.

Each of the first control port 253 and the second control port 255 is coupled to an output port 263 of the detection unit 26.

The detection unit 26 is coupled to the boost converter 22 and configured to detect the power voltage V1 and sent out a control signal to the first control port 253 and the second control port 255 via the output port 263 after comparing the power voltage V1 to a preset voltage. The first control port 253 and the second control port 255 controls the output port 257 to output the voltage of the first input port 251 or the second input port 252. In at least one embodiment, the preset voltage is 4.5V.

When the DC voltage V0 is normal, the power voltage V1 is greater than or equal to the preset voltage, the detection unit 26 outputs a first control signal, the second control port 255 enables the output port 257 to output the power voltage V1 from the second input port 252. The power voltage V1 is provided to the processor 28 and the flash 29 after being reduced by the buck converter 27. In at least one embodiment, the buck converter 27 is a chip typed LTC3569.

When the DC voltage V0 is abnormal, the power voltage V1 is less than the preset voltage, the motherboard 10 is cut off or at low power, the detection unit 26 outputs a second control signal, the first control port 253 enables the output port 257 to output the voltage of the first input port 251, which is the discharge voltage V2. The discharge voltage V2 is provided to the processor 28 and the flash 29 after being reduced by the buck converter 27. Thus, when the motherboard 10 is cut off or low power, the super-capacitor 24 supplies power for the processor 28 and the flash 29, preventing data from being lost or damaged. The first control signal and the second control signal are opposite level voltage signals.

The embodiments shown and described above are only examples. Many details are often found in the art such as the other features of a SSD power supply circuit. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A solid state disk (SSD) power supply circuit comprising:
a processor;
a flash;
a golden finger couplable to a direct current (DC) voltage;
a boost converter coupled to the golden finger and configured to convert the DC voltage to a power voltage;
a super-capacitor charger coupled to the boost converter and receiving the power voltage;
a super-capacitor coupled to the super-capacitor charger and configured to be charged by the super-capacitor charger and output a charge voltage;
a control unit coupled to the processor and the flash and comprising a first input port, coupled to the super-capacitor and configured to receive the charge voltage, and a second input port, coupled to the boost converter and configured to receive the power voltage; and
a detection unit coupled to the boost converter and configured to compare the power voltage with a preset voltage;
wherein, the control unit is configured such that when the power voltage is less than the preset voltage, the control unit outputs the charge voltage of the first input port to the processor and the flash; and
wherein, the control unit is further configured such that when the power voltage is greater than or equal to the preset voltage, the control unit outputs the power voltage of the second input port to the processor and the flash.

2. The SSD power supply circuit of claim 1, further comprising a motherboard, wherein the motherboard comprises a DC power supply circuit, which provides the DC voltage, and an expansion slot coupled to the DC power supply circuit, the golden finger is inserted into the expansion slot to receive the DC voltage.

3. The SSD power supply circuit of claim 2, wherein the expansion slot is a memory card slot.

4. The SSD power supply circuit of claim 1, wherein the control unit further comprises a first control port and a second control port, the first control port is configured to enable the first input port, and the second control port is configured to enable the second input port.

5. The SSD power supply circuit of claim 4, wherein when the power voltage is less than the preset voltage, the detection unit outputs a first control signal to the first control port and the second control port, the first control port enables the first input port, and the second control port disenables the second input port; and when the power voltage is greater than or equal to the preset voltage, the detection unit outputs a second control signal to the first control port and the second control port, the first control port disenables the first input port, and the second control port enables the second input port.

6. The SSD power supply circuit of claim 5, wherein the first control signal and the second control signal are opposite level voltage signals.

7. The SSD power supply circuit of claim 1, further comprising a buck converter coupled to an output port of the control unit, wherein the buck converter is configured to reduce the voltage output from the output port and provide the reduced voltage to the process and the flash.

8. A solid state disk (SSD) power supply circuit comprising:
a processor;
a flash coupled to the processor;
a motherboard comprising a DC power supply circuit, which provides a DC voltage, and an expansion slot coupled to the DC power supply circuit; and
a golden finger inserted into the expansion slot and coupled to the DC voltage;
wherein the golden finger receives the DC voltage and provides the DC voltage to the process and the flash.

9. The SSD power supply circuit of claim 8, wherein the expansion slot is a memory card slot.

10. The SSD power supply circuit of claim 8, further comprising:
a boost converter coupled to the golden finger and configured to convert the DC voltage to a power voltage;
a super-capacitor charger coupled to the boost converter and receiving the power voltage;
a super-capacitor coupled to the super-capacitor charger and configured to be charged by the super-capacitor charger and output a charge voltage;
a control unit coupled to the processor and the flash and comprising a first input port, coupled to the super-capacitor and configured to receive the charge voltage, and a second input port, coupled to the boost converter and configured to receive the power voltage; and
a detection unit coupled to the boost converter and configured to compare the power voltage with a preset voltage;
wherein, the control unit is configured such that when the power voltage is less than the preset voltage, the control unit outputs the charge voltage of the first input port to the processor and the flash; and
wherein, the control unit is configured such that when the power voltage is greater than or equal to the preset voltage, the control unit outputs the power voltage of the second input port to the processor and the flash.

11. The SSD power supply circuit of claim 10, wherein the control unit further comprises a first control port and a second control port, the first control port is configured to enable the first input port, and the second control port is configured to enable the second input port.

12. The SSD power supply circuit of claim 11, wherein when the power voltage is less than the preset voltage, the detection unit outputs a first control signal to the first control port and the second control port, the first control port enables the first input port, and the second control port disenables the second input port; and when the power voltage is greater than or equal to the preset voltage, the detection unit outputs a second control signal to the first control port and the second control port, the first control port disenables the first input port, and the second control port enables the second input port.

13. The SSD power supply circuit of claim 12, wherein the first control signal and the second control signal are opposite level voltage signals.

14. The SSD power supply circuit of claim 10, further comprising a buck converter coupled to an output port of the control unit, wherein the buck converter is configured to reduce the voltage output from the output port and provide the reduced voltage to the process and the flash.
